(19) United States
(12) Patent Application Publication
(10) Pub. No.: US 2006/0024971 A1
(43) Pub. Date: Feb. 2, 2006

(54) Dry etching method using polymer mask selectively formed by CO gas

(75) Inventors: Wan-Jae Park, Suwon-si (KR); Ho-Sen Chang, Suwon-si (KR); Young-Mook Oh, Hwaseong-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/193,199

(22) Filed: Jul. 29, 2005

(30) Foreign Application Priority Data
Jul. 30, 2004 (KR) 2004-60275

(51) Int. Cl. H01L 21/461; H01L 21/302

(52) U.S. Cl. 438/706

(57) ABSTRACT

A dry etching method comprises placing a semiconductor substrate in a reactor, the semiconductor substrate comprising a photoresist pattern formed on an etching target layer, supplying carbon monoxide gas into the reactor to selectively deposit polymer on the photoresist pattern to form a polymer layer, and etching the etching target layer using the photoresist pattern and the polymer layer as an etch mask.

### CROSS-REFERENCE TO RELATED APPLICATION

This application claims priority to Korean Patent Application No. 10-2004-0060275 filed on Jul. 30, 2004, the disclosure of which is incorporated herein by reference in its entirety.

### TECHNICAL FIELD

The present disclosure relates to a method of manufacturing a semiconductor device, and more particularly to a dry etching method using a polymer mask selectively formed on a photoresist pattern by carbon monoxide (CO) gas.

### BACKGROUND

Manufacturing processes of semiconductor devices become more complicated as semiconductor integrated circuits (ICs) become more highly integrated. Thus, semiconductor devices capable of forming ultra-fine patterns are needed by developing a new photoresist material suitable for forming the ultra-fine patterns. However, it is difficult to form fine patterns using a conventional photolithography process because a line width of patterns is smaller than resolution limitation. It is also difficult to form a photoresist pattern having a good profile in the conventional photolithography process.

In a conventional technology for forming fine patterns, reducing a wavelength of an exposure light source is used to improve resolution. For example, in manufacturing a 256 M bit dynamic random access memory (DRAM) with a design rule of 0.25 μm, a krypton fluoride (KrF) excimer laser having a wavelength of 248 μm is used instead of an i-line laser having a wavelength of 365 μm as a light source. To manufacture a DRAM having a capacity exceeding 1 Gbit with a design rule of 0.2 μm, a light source having a shorter wavelength than that of the KrF excimer laser such as an ArF excimer laser having a wavelength of 193 nm is used.

However, light having a short wavelength such as deep ultraviolet rays (UV), KrF excimer laser beam, and ArF excimer laser beam can be absorbed by a photoresist layer. Accordingly, the light having a short wavelength may not reach a bottom portion of the photoresist layer depending on a thickness of the photoresist layer. For example, when an ArF excimer laser beam having a short wavelength of 193 nm (=0.193 μm) is used as an exposure light source to achieve high resolution, a photoresist layer having a thickness of less than 1930 Å (=0.193 μm) is needed for the ArF excimer laser beam not to be absorbed by the photoresist layer. However, due to a poor etching resistance, thin photoresist patterns cannot properly function as an etch mask for an underlying target layer such that a reduction in an etching depth of the target layer may occur.

FIGS. 1A through 1C are sectional views illustrating a poor profile of an interlayer insulating layer 11 due to a low etching resistance of a photoresist pattern 12 when an ArF excimer laser beam is used. Referring to FIG. 1A, an interlayer insulating layer 11 is formed on a semiconductor substrate 10 as an etch layer. To increase resolution, a thickness of a photoresist pattern 12 is reduced. Thus, the photoresist pattern 12 used as an etch mask is not thick enough to properly etch the etch layer 11.

Referring to FIG. 1B, when the etch layer 11 is etched by a conventional anisotropic etching method, the thickness of the photoresist pattern 12 is reduced to a residual photoresist pattern 12′. When the etching process is continuously performed until the thick etch layer 11 is etched away to a predetermined depth, the residual photoresist pattern 12′ located at the upper edge of the etch layer 11 as shown in FIG. 1B is removed. Thus, as shown in FIG. 1C, the residual photoresist pattern 12′ cannot properly function as an etch mask, thereby resulting in the poor profile of the etch layer 11.

### SUMMARY OF THE INVENTION

Exemplary embodiments of the present invention include dry etching methods that use an etch mask selectively formed on a thin photoresist pattern so that high resolution and an excellent etching profile can be achieved.

In one exemplary embodiment of the present invention, a dry etching method comprises placing a semiconductor substrate in a reactor, the semiconductor substrate comprising a photoresist pattern formed on an etching target layer, supplying carbon monoxide gas into the reactor to selectively deposit polymer on the photoresist pattern to form a polymer layer, and etching the etching target layer using the photoresist pattern and the polymer layer as an etch mask.

In another exemplary embodiment of the present invention, a dry etching method comprises placing a semiconductor substrate in a reactor, the semiconductor substrate comprising a photoresist pattern formed on an etching target layer, etching the etching target layer using the photoresist pattern as an etch mask, supplying the carbon monoxide gas into the reactor to selectively deposit polymer on the photoresist pattern to form a polymer layer; and etching the etching target layer using the photoresist pattern and the polymer layer as an etch mask.

It is preferable that an average power applied to the reactor during the depositing of the polymer when supplying the carbon monoxide gas into the reactor is smaller than an average power applied to the reactor during the etching of the etching target layer.

It is preferable that an average pressure applied to the reactor during the depositing of the polymer is higher than an average pressure applied to the reactor during the etching of the etching target layer.

The step of supplying the carbon monoxide gas to deposit polymer and the step of etching the etching target layer can be repeatedly performed to etch the etching target layer to a predetermined depth. The etching target layer can be formed of a material capable of preventing a polymer reaction between the etching target layer and the carbon monoxide gas.

These and other exemplary embodiments, aspects, features and advantages of the present invention will become apparent from the following detailed description of exemplary embodiments, which is to be read in connection with the accompanying drawings.

### BRIEF DESCRIPTION OF THE DRAWINGS

FIGS. 1A through 1C are sectional views illustrating a process of etching an insulating layer in a conventional dry etching method.

FIG. 2 is a flowchart illustrating a dry etching method according to an exemplary embodiment of the present invention.

FIG. 3 is a sectional view of a semiconductor substrate in a process of a dry etching method according to an exemplary embodiment of the present invention.

FIGS. 4A and 4B illustrate reactors used in a dry etching method according to an exemplary embodiment of the present invention.

FIG. 5 is a scanning electron microscope (SEM) photograph illustrating a polymer layer, which is formed in a process of a dry etching method according to an exemplary embodiment of the present invention.

FIGS. 6 and 7 are sectional views of a semiconductor substrate in a dry etching method according to an exemplary embodiment of the present invention.

FIG. 8 is a graph illustrating an improvement of selectivity between an etch layer and a photoresist pattern when selectively forming a polymer layer before an etching step.

FIG. 9 is a flowchart illustrating a dry etching method according to another exemplary embodiment of the present invention.

FIGS. 10 through 12 are sectional views of a semiconductor substrate illustrating a dry etching method according to another exemplary embodiment of the present invention.

### DETAILED DESCRIPTION OF EXEMPLARY EMBODIMENTS

Exemplary embodiments of the present invention will now be described more fully hereinafter below with reference to the accompanying drawings. This invention may, however, be embodied in different forms and should not be construed as limited to the exemplary embodiments set forth herein. Rather, these exemplary embodiments are provided so that this disclosure will be through and complete, and will fully convey the scope of the invention to those skilled in the art.

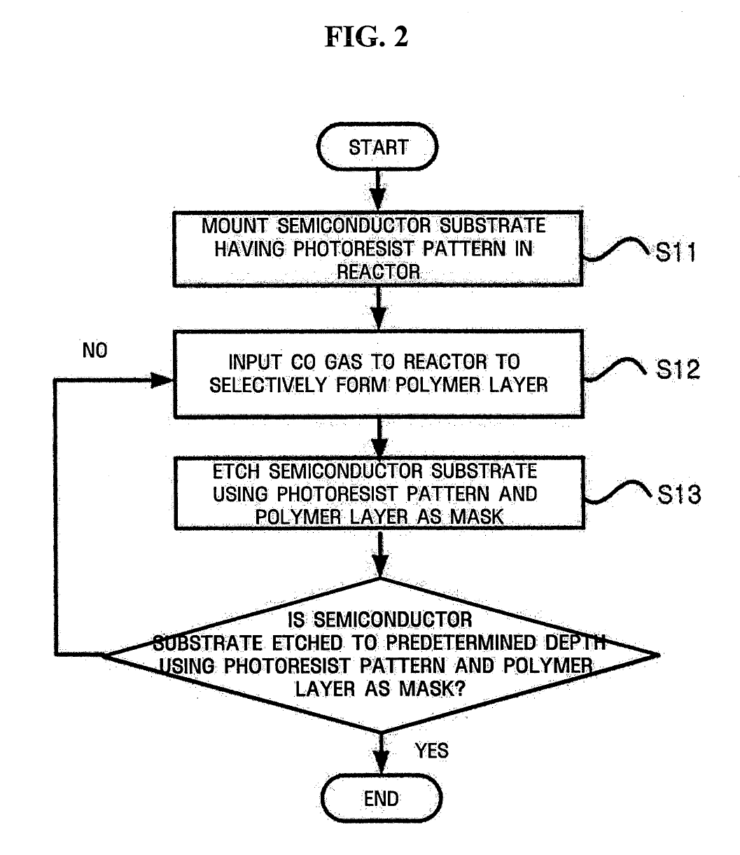

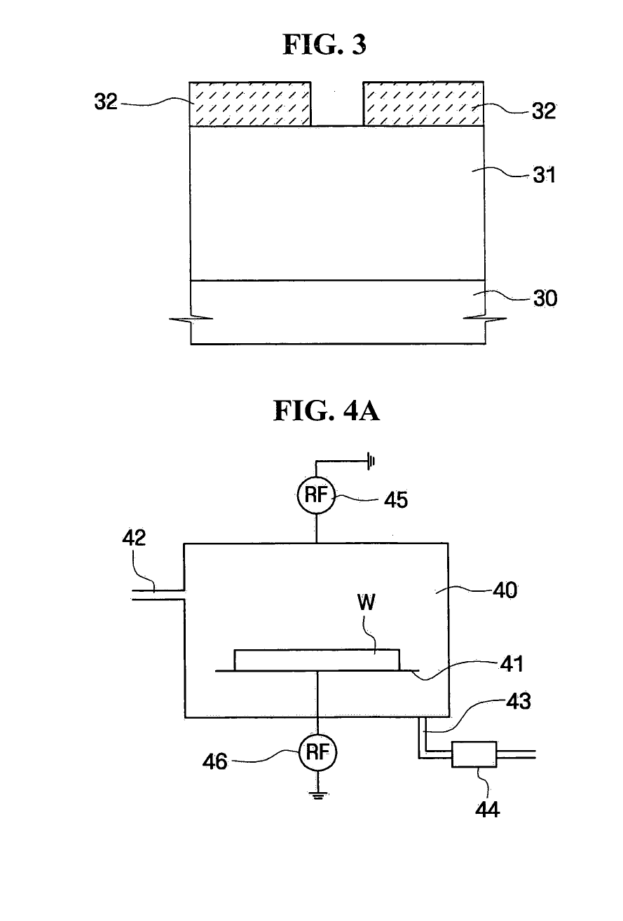

A dry etching method according to an exemplary embodiment of the present invention is described with reference to FIG. 2 through FIG. 7. Referring to FIG. 2, a semiconductor substrate having a photoresist pattern formed on an etching target layer is placed in a reactor (S11). Referring to FIG. 3, an etching target layer 31 is formed on a semiconductor substrate 30 by chemical vapor deposition (CVD). The etching target layer 31 may be formed of a material that can prevent a polymer reaction between the etching target layer 31 and carbon monoxide gas. Thereafter, a photoresist is coated on the entire surface of the etching target layer 31. The photoresist can be formed with a thickness of from about 0.5 μm to about 1.2 μm. According to an exemplary embodiment of the present invention, a photoresist with 0.7 μm is used. To pattern the photoresist, i-line, KrF, or ArF excimer laser may be used as a light source. The ArF excimer laser having a shorter wavelength than the i-line or KrF excimer laser can be used for exposure and development of the photoresist to achieve higher resolution.

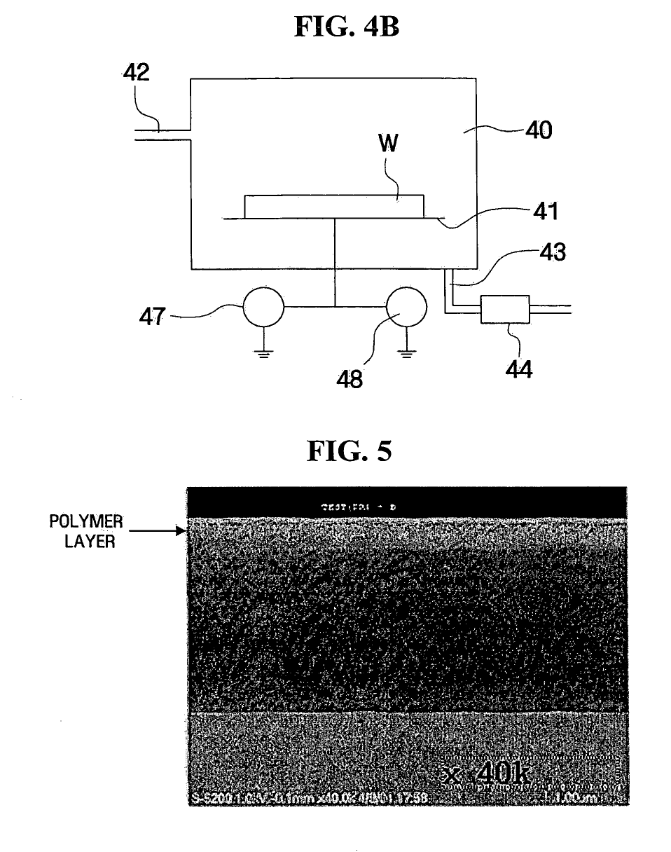

The semiconductor substrate W having a photoresist pattern 32 is positioned in a reactor 40 of FIG. 4A or 4B for dry etching. The reactor 40 may be, for example, any of a source/bias power system as shown in FIG. 4A or a dual frequency power system as shown in FIG. 4B.

Referring to FIG. 4A, the reactor 40 using the source/bias power system includes a supporter 41 on which a semiconductor substrate W to be etched is mounted. The supporter 41 includes a heater or a cooling unit (not shown) for controlling the temperature of the semiconductor substrate W. In addition, the reactor 40 includes a gas inlet 42 through which plasma gas or etching gas is supplied, and an exhaust outlet 43 and a pump 44 for exhausting gas and controlling an internal pressure. A source power supply 45 supplying a power for generating plasma is connected to an upper portion of the reactor 40, and a bias power supply 46 supplying a power to the semiconductor substrate W is connected to the supporter 41. The source power supply 45 supplies power to convert the etching gas into plasma. The bias power supply 46 supplies power to create a potential difference enabling the plasma to collide against the semiconductor substrate W.

Referring to FIG. 4B, the reactor 40 uses a dual frequency power system. including a high frequency power supply 47 and a low frequency power supply 48 that are connected to the supporter 41 on which a semiconductor substrate W is mounted. As essentially described above, the semiconductor substrate W having the etching target layer and the photoresist pattern is mounted on the supporter of the reactor (S11). Thereafter, CO gas is supplied into the reactor to form a polymer layer on the photoresist pattern (S12).

Referring to FIGS. 4A and 4B, CO gas is supplied into the reactor 40 through the gas inlet 42. The CO gas supplied into the reactor 40 becomes a CO* gas (where * represents an excited state) by applying a power from the source power supply 45 or applying a power from the high frequency power supply 47.

In another exemplary embodiment of the present invention, the CO gas may also become excited by simultaneously applying a power from the source power supply 45 and the bias power supply 46, wherein the power supplied from the bias power supply 46 is smaller than the power supplied from the source power supply 45. In still another exemplary embodiment of the present invention, the CO gas may also become excited by simultaneously applying a power from the high frequency power supply 47 and a power from the low frequency power supply 48, wherein a power supplied from the low frequency power supply 48 is smaller than the power supplied from the high frequency power supply 47.

In exemplary embodiments, an average power applied to the reactor that is used for exciting the CO gas is smaller than an average power applied thereto during a subsequent etching process, which will later be described. Thus, the CO* gas scarcely collides with the etching target layer. In an exemplary embodiment using the source/bias power system for exciting the CO gas, as shown in FIG. 4A, the source power supply 45 and the bias power supply 46 may apply a power ranging from about 500 W to about 1,500 W and from about 0 W to about 500 W, respectively to the reactor 40. In an exemplary embodiment using the dual frequency power system for exciting the CO gas, as shown in FIG. 4B, the high frequency power supply 47 and the low frequency power supply 48 apply a power ranging from about 200 W to about 500 W and from about 0 W to about 100 W, respectively to the reactor 40. The CO* gas is selectively deposited on the photoresist pattern, of the semiconductor substrate W in a polymer phase, i.e., CₓH_{y}O_{z}.

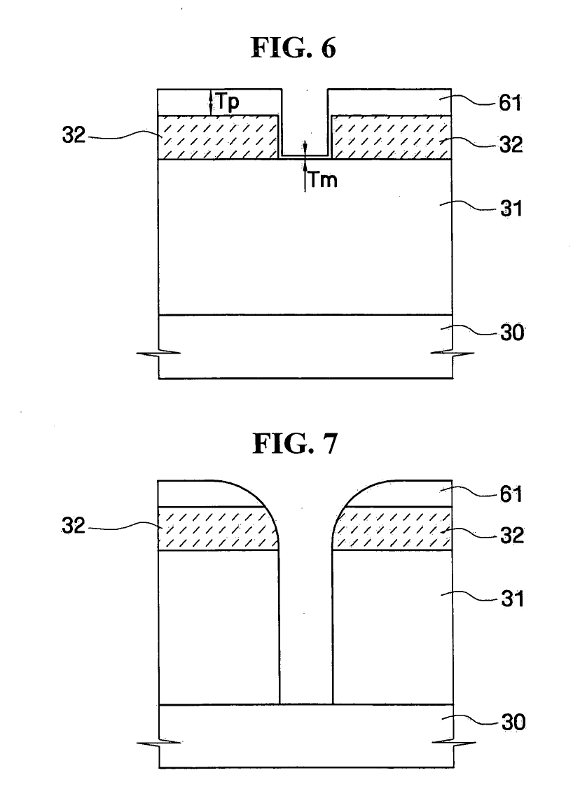

FIG. 5 is a scanning electron microscope (SEM) photograph illustrating a polymer layer formed on the photoresist pattern 32. Referring to FIG. 6, to selectively form a polymer layer 61, a power is applied from the source power supply (45 shown in FIG. 4A) or from the high frequency power supply (47 shown in FIG. 4B).

In another exemplary embodiment, a power may be applied from both the source power supply 45 and the bias power supply (46 shown in FIG. 4A), wherein a power supplied from the bias power supply 46 is smaller than the power supplied from the source power supply 45. In still another exemplary embodiment, a power may be applied from both the high frequency power supply 47 and the low frequency power supply (48 shown in FIG. 4B), wherein a power supplied from the low frequency power supply is smaller than the power supplied from the high frequency power supply 47. Most of the CO* gas can be used in deposition of the polymer layer 61 rather than in etching of the etching target layer 31 because the bias power supply 46 or the low frequency power supply 48 supplies a power to create a potential difference enabling the plasma-phase etching gas to collide against the semiconductor substrate W.

Accordingly, when no power from the bias power supply 46 or the low frequency power supply 48 is applied or when a power lower than the source power supply 45 or the high frequency power supply 47 is applied during the etching for the etching target layer, the CO* gas scarcely collides with the semiconductor substrate W while deposition of the polymer predominantly occur.

Under the applications of power essentially described above, the polymer layer 61 is selectively formed only on the photoresist pattern 32. Although the polymer is deposited on the etching target layer 31 where the photoresist pattern 32 is not formed, the thickness Tm of the polymer deposited on the etching target layer 31 is substantially smaller than the thickness Tp of the polymer layer 61 formed on the photoresist pattern 32.

To selectively form the polymer layer 61, an average internal pressure of the reactor (40 shown in FIGS. 4A and 4B) is required to be higher than the average pressure applied during the etching of the etching target layer 31. When using a pressure of about 50 mT or higher during the etching of the etching target layer 31, the average internal pressure of the reactor can be over 100 mT. When using a pressure ranging from about 10 to about 100 mT during the etching of the etching target layer 31, the average internal pressure of the reactor can be over 30 mT. A thickness and a profile of the polymer layer 61 deposited may vary depending on processing conditions such as an average power applied to the reactor and/or internal pressure of the reactor.

The thickness Tm of the polymer layer 61 deposited on the etching target layer 31 where the photoresist pattern 32 is not formed is smaller than the thickness Tp of the polymer layer 61 formed on the photoresist pattern 32. Subsequently, the etching target layer 31 is etched using the photoresist pattern 32 and the polymer layer 61 as an etch mask (S13).

Referring again to FIGS. 4A and 4B, etching gas is supplied into the reactor 40 through the inlet 42. The semiconductor substrate W having the photoresist pattern 32 and the polymer layer 61 is placed on the supporter 41. Then, dry etching is performed by applying a power from the source power supply 45/the bias power supply 46 or from the high frequency power supply 47/the low frequency power supply 48 to the reactor 40, wherein the semiconductor substrate W is mounted on the supporter 41. Examples of the etching gas include CₓF_{y} based gases or CₐH_{b}Fₑ based gases such as CF₄, CHF₃, C₂F₆, C₄F₈, CH₂F₂, CH₃F, CH₄, C₂H₂, and C₄F₆. Inert gas, such as He, Ar, Xe, or I, may further be supplied to the reactor 40 to generate plasma.

An appropriate power level for generating the plasma or accelerating the generated plasma depends on the type of an etching apparatus used. In the case of using the source/bias power system, the source power supply 45 and the bias power supply 46 may supply a power ranging from about 1,000 W to about 2,000 W and from about 700 to about 2,000 W, respectively. In the case of using the dual frequency power system, the high frequency power supply 47 and the low frequency power supply 48 may supply a power ranging from about 300 W to about 1,500 W and from about 300 to about 800 W, respectively.

The deposition of the polymer and the dry etching can be repeatedly performed while replenishing the polymer layer etched away, allowing a relatively thick etching target layer to be etched further. Referring to FIG. 7, the photoresist pattern 32 and the polymer layer 61 function as an etch mask so that the etching target layer 31 can be etched without a profile failure.

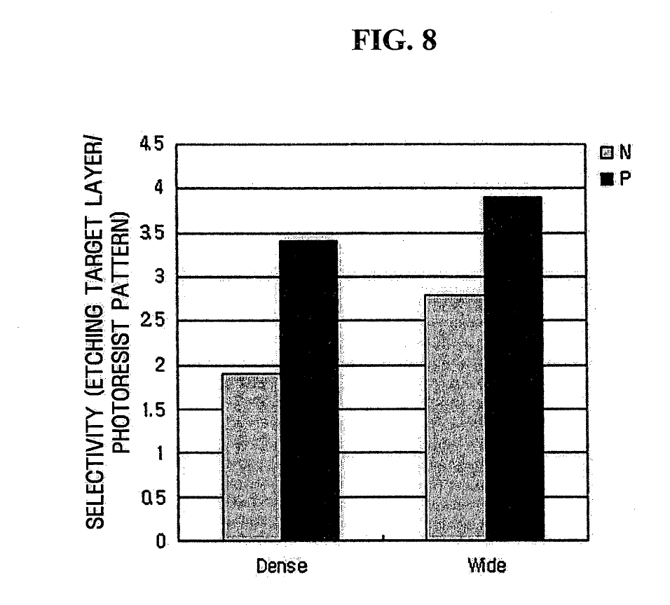

FIG. 8 is a graph illustrating improvement in selectivity, also called a selective ratio, of an etching target layer with respect to a photoresist pattern when selectively forming a polymer layer before etching the etching target layer. Referring to FIG. 8, the selective ratios are improved when a polymer layer is selectively formed on the photoresist pattern, as represented by reference character P, compared to the case where a selective polymer, as represented by reference character N. A dense photoresist pattern, i.e., a 160:160 (nm) line-and-space pattern, and a wide photoresist pattern, i.e., a 160:650 (nm) line-and-space pattern are used, respectively.

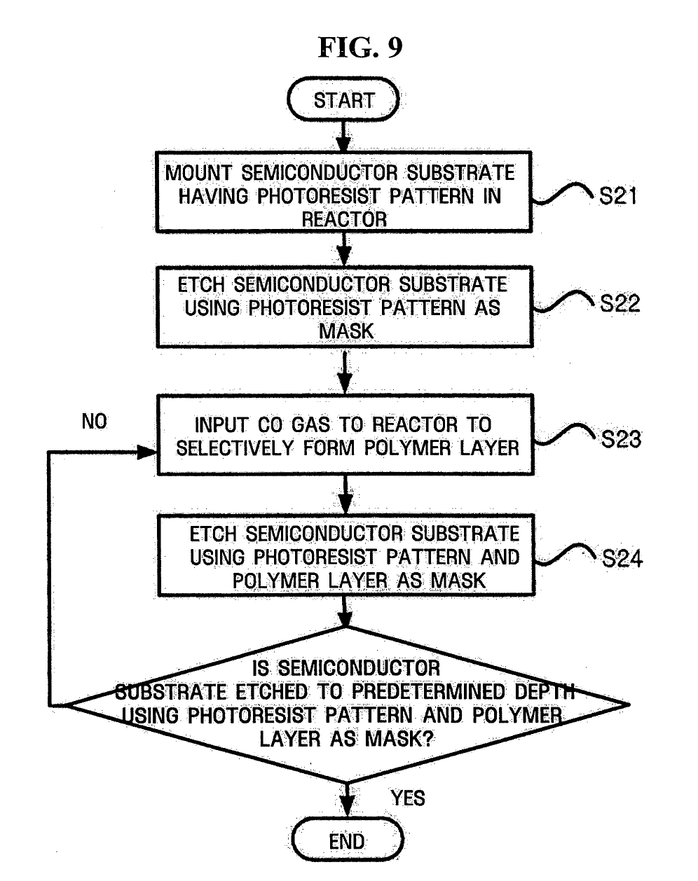

A dry etching method according to another exemplary embodiment of the present invention is described with reference to FIG. 9 through FIG. 12. Referring to FIG. 9, a semiconductor substrate having a photoresist pattern formed on an etching target layer is placed in a reactor (S21). The process S21 is essentially similar to the process S11 as described above. Subsequently, the etching target layer is etched using the photoresist pattern as an etch mask for a predetermined time (S22).

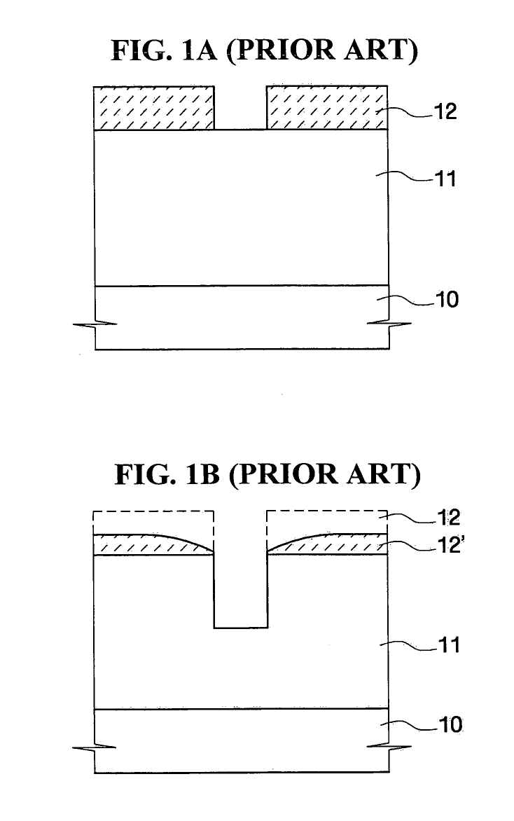

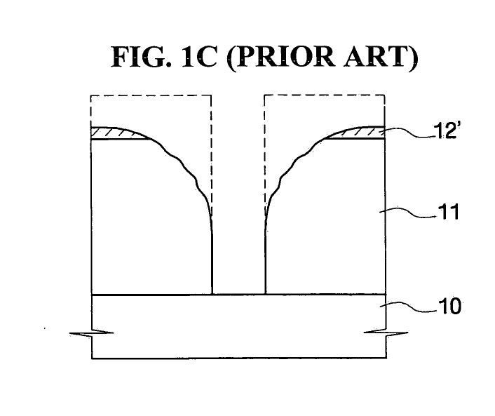

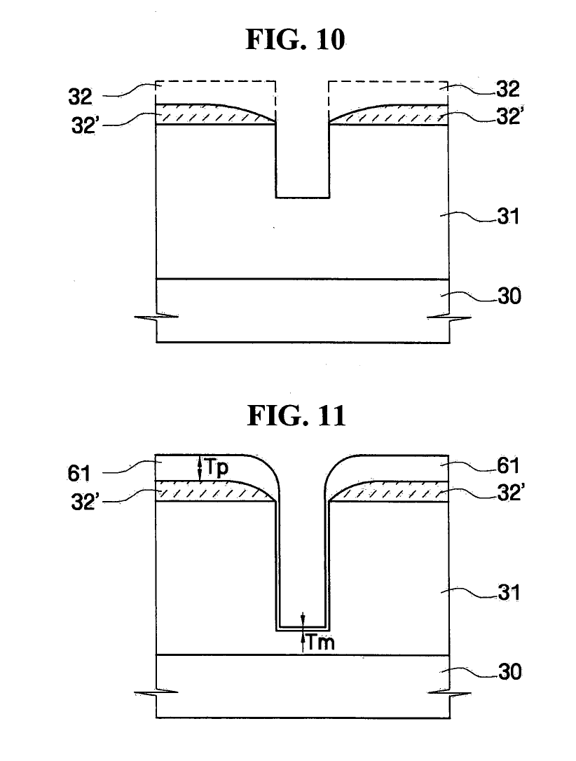

Referring to FIG. 10, under the power application conditions essentially described above in FIGS. 4A and 4B, the etching target layer 31 under the photoresist pattern 32 is etched for a predetermined time, for example, about one to three minutes, using the photoresist pattern 32 as an etch mask, thereby etching the etching target layer 31 to a predetermined depth. In this case, the etching process can be continuously performed until the photoresist pattern 32 are used up so that it cannot function as an etch mask. Here, a residual photoresist pattern incapable of functioning as an etch mask is denoted by reference numeral 32′. If the etching process is further performed, deterioration in the profile of the etching target layer 31 cannot be avoided as shown in FIG. 1C.

Thereafter, CO gas is supplied into the reactor to selectively deposit polymer on the residual photoresist pattern 32′, thereby forming a polymer layer 61 (S23). Then, the etching target layer 31 is etched using the photoresist pattern 32′ and the polymer layer 61 as an etch mask (S24). Conditions for the application of power and pressure in the processes S23 and S24 are essentially the same as conditions for the application of power and pressure in the processes S12 and S13 as described above. For example, an average power applied to the reactor during the depositing of the polymer when supplying the carbon monoxide gas into the reactor is smaller than an average power applied to the reactor during the etching of the etching target layer. An average pressure applied to the reactor during the depositing of the polymer is higher than an average pressure applied to the reactor during the etching of the etching target layer.

Referring to FIG. 11, the polymer layer 61 is selectively formed on the residual photoresist pattern 32′. Although the polymer is deposited on the etching target layer 31 where the photoresist pattern 32′ is not formed, the thickness Tm of the polymer deposited on the etching target layer 31 is substantially small compared to the thickness Tp of the polymer layer 61 formed on the residual photoresist pattern 32′.

In addition, to selectively form the polymer layer 61 on the residual photoresist pattern 32′, an average internal pressure of the reactor (40 shown in FIGS. 4A and 4B) is required to be higher than the average pressure applied during the etching of the etching target layer 31. When using a pressure of 50 mT or higher, the average internal pressure of the reactor is preferably over 100 mT. When using a pressure ranging from 10 to 100 mT, the average internal pressure of the reactor is preferably over 30 mT. A thickness and a profile of the polymer layer 61 deposited may vary according to a change in processing conditions, including an average power applied to the reactor and/or internal pressure of the reactor.

Subsequently, the etching target layer 31 is etched using the residual photoresist pattern 32′ and the polymer layer 61 as an etch mask (S24). After forming the polymer layer (61 shown in FIG. 10) in the above-described manner, the power applied to the reactor (40 shown in FIGS. 4A and 4B) and the internal pressure of the reactor 40 are restored to levels for the etching process. Then, etching is performed for a predetermined time, for example, about one to two minutes.

Before the polymer layer 61 and the residual photoresist pattern 32 are used up due to continued performance of the etching so that they cannot function as an etch mask, polymer is selectively deposited on the photoresist pattern to form a polymer layer (S22). Then, the etching target layer 31 is dry etched using the residual photoresist pattern 32′ and the polymer layer 61 as an etch mask S23, thereby etching the etching target layer 31 to a desired depth.

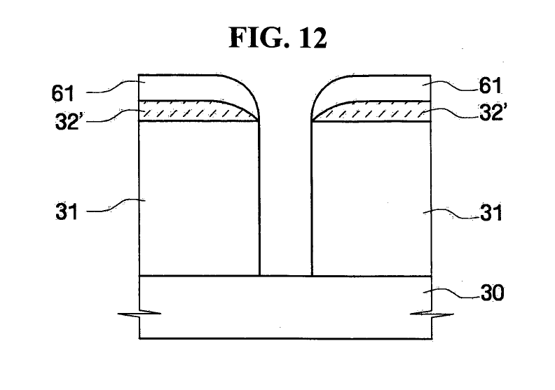

In this case, the deposition of the polymer and the dry etching may be repeatedly performed more than once while replenishing the polymer layer etched away, allowing a relatively thick etching target layer to be etched further. As a result, as shown in FIG. 12, the etching target layer 31 can be etched to a predetermined depth without a deterioration in the profile using the residual photoresist pattern 32′ and the polymer layer 61 functioning as an etch mask. The dry etching method according to exemplary embodiments of the present invention can be applied to a process of forming a contact hole, as well as lines and spaces.

Although exemplary embodiments have been described herein with reference to the accompanying drawings, it is to be understood that the present invention is not limited to such exemplary embodiments, and that various other changes and modifications may be affected therein by one of ordinary skill in the related art without departing from the scope or spirit of the invention. All such changes and modifications are intended to be included within the scope of the invention as defined by the appended claims.

What is claimed is:

1. A dry etching method comprising:
placing a semiconductor substrate in a reactor, the semiconductor substrate comprising a photoresist pattern formed on an etching target layer;
supplying carbon monoxide gas into the reactor to selectively deposit polymer on the photoresist pattern to form a polymer layer; and
etching the etching target layer using the photoresist pattern and the polymer layer as an etch mask.

2. The method of claim 1, wherein an average power applied to the reactor during the depositing of the polymer when supplying the carbon monoxide gas into the reactor is smaller than an average power applied to the reactor during the etching of the etching target layer.

3. The method of claim 1, wherein an average pressure applied to the reactor during the depositing of the polymer is higher than an average pressure applied to the reactor during the etching of the etching target layer.

4. The method of claim 1, wherein the step of supplying the carbon monoxide gas to selectively deposit polymer and the step of etching the etching target layer are repeatedly performed to etch the etching target layer to a predetermined depth.

5. The method of claim 1, wherein the etching target layer is formed of a material capable of preventing a polymer reaction between the etching target layer and the carbon monoxide gas.

6. A dry etching method comprising:
placing a semiconductor substrate in a reactor, the semiconductor substrate comprising a photoresist pattern formed on an etching target layer;
etching the etching target layer using the photoresist pattern as an etch mask;
supplying the carbon monoxide gas into the reactor to selectively deposit polymer on the photoresist pattern to form a polymer layer; and
etching the etching target layer using the photoresist pattern and the polymer layer as an etch mask.

7. The method of claim 6, wherein an average power applied to the reactor during the depositing of the polymer when supplying the carbon monoxide gas into the reactor is smaller than an average power applied to the reactor during the etching of the etching target layer.

8. The method of claim 6, wherein an average pressure applied to the reactor during the depositing of the polymer is higher than an average pressure applied to the reactor during the etching of the etching target layer.

9. The method of claim 6, wherein the step of supplying the carbon monoxide gas to selectively deposit polymer and the step of etching the etching target layer are repeatedly performed to etch the etching target layer to a predetermined depth.

10. The method of claim 6, wherein the etching target layer is formed of a material capable of preventing a polymer reaction between the etching target layer and the carbon monoxide gas.
